(19) United States
(12) Patent Application Publication
(10) Pub. No.: US 2024/0074069 A1
(43) Pub. Date: Feb. 29, 2024

(54) DISPLAY PANEL STRUCTURE APPLICABLE IN 86 BOX

(71) Applicant: SHENZHEN QIMING CLOUD TECHNOLOGY CO., LTD, Shenzhen, Guangdong (CN)

(72) Inventors: Zhougang WEN, Shenzhen, Guangdong (CN); Yunxiang MU, Shenzhen, Guangdong (CN); Hui LI, Shenzhen, Guangdong (CN); Honggang WANG, Shenzhen, Guangdong (CN)

(21) Appl. No.: 18/259,544

(22) PCT Filed: Feb. 24, 2021
(86) PCT No.: PCT/CN2021/077554

§ 371 Date: Jun. 27, 2023

(30) Foreign Application Priority Data
Feb. 8, 2021 (CN) 202120363451.7

(51) Int. Cl. H05K 5/00; G02F 1/1333; H04R 1/02

(52) U.S. Cl. CPC H05K 5/0018; G02F 1/133317; G02F 1/13338; H04R 1/028; H04R 2499/15

(57) ABSTRACT

The display panel structure suitable for 86 type electrical mounting junction boxes, comprising a limit board (10), a power supply board (30), a PCB board (40), middle frames (50), a display screen (60) and a display screen driving board (601), wherein the middle frames (50) are provided with frames capable of enclosing inner structure thereof in a closed manner; a FPC board (70) is further comprised; the FPC board (70) engages with one of the frames of the middle frames (50) and is installed on the frames; microphones (80) and a temperature and humidity sensor (90) are provided on the FPC board (70); the display panel structure further comprises a speaker (100); and the speaker (100) is located on a side of the middle frames (50) far away from the microphones (80) and the temperature and humidity sensor (90).

### TECHNICAL FIELD

The present application relates to the technical field of panel mounting, in particular to a display panel structure suitable for 86 type electrical mounting junction boxes.

### BACKGROUND TECHNOLOGY

With the increasing popularity of smart homes and smart household appliances, the 86-type smart home control panels with integrated color capacitive touchscreen LCD displays have gradually appeared, and users' expectations on functions of the 86-type smart home control panels have gradually increased. The traditional on-off function can no longer meet needs of the users, and some of the 86-type smart home control panel products with the microphone function currently in use interfere with the speaker thereof, which may affect use experiences adversely.

In view of the above, it is necessary to further optimize panel structures of the 86-type smart home control panels.

### SUMMARY OF THE INVENTION

In view of the above problems, the present application provides a display panel structure suitable for 86 type electrical mounting junction boxes, aiming at improving modularity, making the structure more compact and reducing interferences between speakers and microphones at the same time.

In order to solve the above technical problems, the present application provides the display panel structure suitable for 86 type electrical mounting junction boxes, comprising a limit board, a power supply board, a PCB board (printed circuit board), middle frames, a display screen and a display screen driving board, wherein the middle frames are provided with frames capable of enclosing a inner structure, wherein:
the display panel structure further comprises a FPC board (flexible printed circuit board), which engages with one of the frames of the middle frames and is installed on the frame;

microphones and a temperature and humidity sensor are provided on the FPC board; and
the display panel structure further comprises a speaker; the speaker is located in a speaker hole located on a side of the middle frames far away from the microphones and the temperature and humidity sensor.

Further, the display panel structure further comprises a back cover film; the back cover film is located between the limit board and the power supply board.

Wherein, there are at least two microphones.

Wherein, the back cover film comprises PVC plastic film.

Preferably, the display screen is an integrated module in which a multicolor LCD screen and a capacitive touch screen are attached.

Further, the PCB board is provided with a voice interaction module; the voice interaction module is electrically connected with the microphones and the speaker respectively.

Further, the integrated module in which the multicolor LCD screen and the capacitive touch screen are attached adopts an integrated FPC interface, and the multicolor LCD screen and the capacitive touch screen are electrically connected together.

The present application has the beneficial effects that: different from the prior art, the display panel structure suitable for 86 type electrical mounting junction boxes provided by the present application, comprising the limit board, the power supply board, the PCB board, the middle frames, the display screen and the display screen driving board; the middle frames are provided with frames capable of enclosing a inner layer structure; wherein, the display panel structure further comprises a FPC board; the FPC board engages with one of the frames of the middle frames and is installed on the frames; microphones and a temperature and humidity sensor are provided on the FPC board; the display panel structure further comprises a speaker; the speaker is located on a side of the middle frames far away from the microphones and the temperature and humidity sensor; through the use of the FPC board, the microphones are separated from the speaker, which improves modularity of the product structure, makes the structure more compact and reduces interferences between a speaker and microphones at the same time.

### DESCRIPTION OF DRAWINGS

In order to more clearly explain the embodiments of the present application or the technical solutions the prior art, the following will briefly introduce the drawings needed in the descriptions of the embodiments or the prior art. Obviously, the drawings in the following descriptions are only some of the embodiments of the present application. For those skilled in this field, other drawings can be obtained according to the structure shown in these drawings without creative work.

FIG. 1 is an explosive view of a display panel structure suitable for 86 type electrical mounting junction boxes provided by the present application; and

FIG. 2 is a schematic installation diagram of the display panel structure suitable for 86 type electrical mounting junction boxes provided by the present application.

### DESCRIPTION OF REFERENCE NUMBERS OF THE FIGURES

limit board 10, back cover film 20, power supply board 30, PCB board 40, middle frame 50, speaker hole 501, display screen 60, display screen driver board 601, FPC board 70, microphone 80, temperature and humidity sensor 90 and speaker 100.

The realization, functional characteristics and advantages of purposes of the present application will be further explained with reference to the attached drawings and embodiments.

### EMBODIMENTS

In the following, technical solutions in the embodiments of the present application will be clearly and completely described in combination with the attached drawings. Obviously, the described embodiments are only some of the embodiments of the present application. Based on the embodiments of the present application, all other embodiments obtained by those skilled in this field without creative labor belong to the protective scope of the present application.

It should be noted that all directional indications such as up, down, left, right, front, back, etc. in the embodiments of the present application are only used to explain relative position relationships and movement situations between components in certain postures as shown in the attached drawings. If the specific postures change, the directional indications change accordingly.

In addition, descriptions referring to “first” and “second” in the present application are only used for descriptive purposes, and cannot be understood as indicating or implying their relative importance or implicitly indicating the number of indicated technical features. Therefore, the features described with “first” and “second” comprise at least one of these features explicitly or implicitly. In addition, the technical solutions of various embodiments can be combined with each other to the extent that those of ordinary skill in the art can realize. When the combination of technical solutions is contradictory or unrealistic, it should be considered that the combination of technical solutions does not exist and is not within the protective scope of the present application.

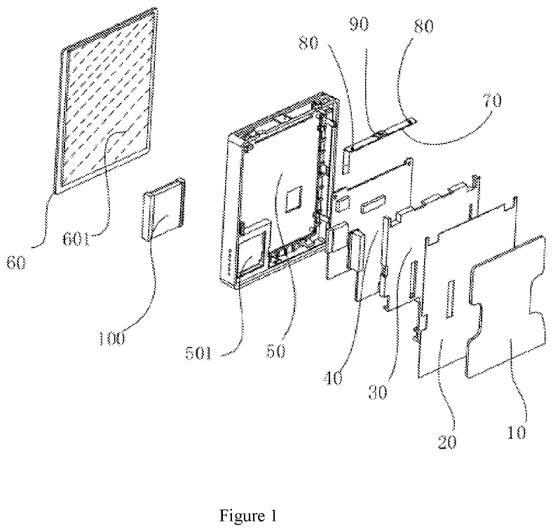

Please refer to FIG. 1, the present application provides an exploded view of a display panel structure suitable for 86 type electrical mounting junction boxes.

The display panel structure comprises:
a limit board 10, a power supply board 30, a PCB board 40, middle frames 50, a display screen 60 and a display screen driving board 601, wherein the middle frames 50 are provided with frames capable of enclosing inner structure thereof in a closed manner.

In some embodiments, in order to realize the multi-function of products, additional functional components are usually added to the display panel structure. For example, the display panel structure also comprises a FPC board 70, which engages with one of the frames of the middle frames 50 and is installed on the frames; with the FPC board 70, it is convenient to install the additional functional components on the FPC board 70 which can be used to adapt to different sub-components. For example, microphones 80 and a temperature and humidity sensor 90 can be provided on the FPC board 70.

It can be understood that the microphones 80 can be used for voice collection, recording and voice interaction scenes. The temperature and humidity sensor 90 is usually located in the center of the FPC board, and is used to sense temperature and humidity of the environment and display the information through the display screen 60.

In some embodiments, the speaker hole 501 is preset in the middle frames 50 of the display panel structure. With the development of intelligent products, more and more products will have voice broadcast function, which makes the content of products more abundant. The speaker hole 501 is reserved on the middle frames 50 as required, which can make full use of the space and make the whole structure compact.

Further, in order to reduce acoustic interferences between the microphones 80 and a speaker 100, the speaker hole 501 is located on the side of the middle frames 50 far away from the microphones 80 and the temperature and humidity sensor 90, and the speaker 100 can be installed on the speaker hole 501.

Preferably, the display panel structure further comprises a back cover film 20; the back cover film 20 is located between the limit board 10 and the power supply board 30. For some products installed with screws, the back cover film 20 can be used for cover installation positioning holes and the speaker 100, so that surface display is more pleasant in appearance; different specialized pictures can be customized for different customers; and the back cover film is PVC plastic film.

Wherein, there are usually at least two microphones 80, which is convenient for collecting sound in multiple directions.

Preferably, the display screen 60 is an integrated module in which a multicolor LCD screen and a capacitive touch screen are attached.

Further, the PCB board 40 is provided with a voice interaction module, which is electrically connected with the microphones 80 and the speaker 100 respectively.

Further, the integrated module in which the multicolor LCD screen and the capacitive touch screen are attached adopts an integrated FPC interface, and the multicolor LCD screen and the capacitive touch screen are electrically connected together.

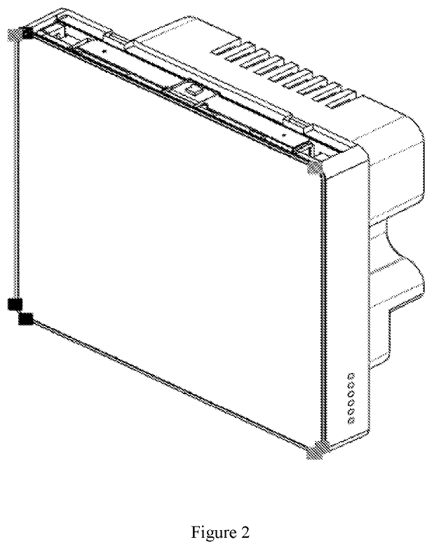

Please refer to FIG. 2 which is a schematic installation diagram of the display panel structure suitable for 86 type electrical mounting junction boxes provided by the present application.

Optionally, the middle frames 50 are provided with the frames enclosing the display screen 60 in a closed manner. Understandably, the frames may not be used for the popular full-screen products, but the non-full screens can protect the screens thereof by making use of the frames.

In some embodiments, the middle frames 50 can be made of aluminum alloy materials (6061 or 7075 or 6063) and produced by CNC (Computer numerical control) processes, or they can be made of ABS+PC (polyacrylonitrile and polycarbonate) mixed materials through injection molds.

Further, the display screen 60 is the integrated module in which the multicolor LCD screen and the capacitive touch screen are attached, wherein the integrated module refers to an integrated display touch module made of the multicolor LCD screen (TFT-LCD) and the capacitive touch screen (CTP) by using double-sided adhesive foam as frame bonding or optical adhesive (OCA) as full bonding.

Wherein, the integrated module in which the multicolor LCD screen and the capacitive touch screen are attached can be compatible with different LCD screen resolutions, such as 3.95-inch multicolor LCD screens with resolutions of 720×720 and 480×480, which is convenient to meet upgrade requirements of product specifications.

Wherein, the capacitive touch screen has a structure where a glass cover plate and glass are stacked.

In some embodiments, the bonding mode of the multicolor LCD screen and the capacitive touch screen is frame bonding.

In some embodiments, the bonding mode of the multicolor LCD screen and the capacitive touch screen is complete bonding.

Further, the integrated module in which the multicolor LCD screen and the capacitive touch screen are attached adopts an integrated FPC interface, and the multicolor LCD screen and the capacitive touch screen are electrically connected together.

The above are only the preferred embodiments of the present application and do not limit the exclusive scope of the present application. Any equivalent replacement made based on the contents of the description and the drawings within the idea of the present invention, or direct or indirect use of the present invention in other related technical fields are covered in the protection scope of the present invention.

1. A display panel structure suitable for 86 type electrical mounting junction boxes, comprising a limit board, a power supply board, a PCB board (printed circuit board), middle frames, a display screen and a display screen driving board; the middle frames are provided with frames capable of enclosing a inner layer structure; wherein:
the display panel structure further comprises a FPC board (flexible printed circuit board); the FPC board engages with one of the frames of the middle frames and is installed on the frames;
microphones and a temperature and humidity sensor are provided on the FPC board;
the display panel structure further comprises a speaker; and the speaker is located in a speaker hole located on a side of the middle frames far away from the microphones and the temperature and humidity sensor.

2. The display panel structure according to claim 1, wherein:
the display panel structure further comprises a back cover film; the back cover film is located between the limit board and the power supply board.

3. The display panel structure according to claim 1, wherein:
there are at least two microphones.

4. The display panel structure according to claim 1, wherein:
the back cover film comprises PVC plastic film.

5. The display panel structure according to claim 1, wherein:
the display screen is an integrated module in which a multicolor LCD screen and a capacitive touch screen are attached.

6. The display panel structure according to claim 5, wherein:
a voice interaction module is provided on the PCB board; and the voice interaction module is electrically connected with the microphones and the speaker respectively.

7. The display panel structure according to claim 5, wherein:
the integrated module in which the multicolor LCD screen and the capacitive touch screen are attached adopts an integrated FPC interface, and the multicolor LCD screen and the capacitive touch screen are electrically connected together.
